(19) United States
(12) Patent Application Publication
(10) Pub. No.: US 2025/0311489 A1
(43) Pub. Date: Oct. 2, 2025

(54) LIGHT EMITTING DIODE AND MANUFACTURING METHOD THEREOF

(71) Applicant: ASUSTeK COMPUTER INC., Taipei City (TW)

(72) Inventors: Ching-Hsin Lin, Taipei City (TW); Chin-An Tseng, Taipei City (TW); Chia-Lei Yu, Taipei City (TW); Jian-Jang Huang, Taipei City (TW); Yu-Hsiang Chang, Taipei City (TW); Yuan-Chao Wang, Taipei City (TW)

(73) Assignee: ASUSTeK COMPUTER INC., Taipei City (TW)

(21) Appl. No.: 19/019,524

(22) Filed: Jan. 14, 2025

(30) Foreign Application Priority Data
Mar. 27, 2024 (TW) 113111376

(51) Int. Cl. H10H 20/81; H10H 20/01; H10H 20/819; H10H 20/84

(52) U.S. Cl. CPC H10H 20/8215; H10H 20/017; H10H 20/819; H10H 20/84

(57) ABSTRACT

A light emitting diode includes a first type semiconductor pattern disposed over a substrate, an active pattern disposed over the first type semiconductor pattern, a second type semiconductor pattern disposed over the active pattern, an ion implantation region and a plurality of electrodes. A polarity of the first type semiconductor pattern is opposite to a polarity of the second type of the second type semiconductor pattern. The ion implantation region at least surrounds and encapsulates a side wall of the second type semiconductor pattern. The electrodes are disposed over the first type semiconductor pattern and the second type semiconductor pattern respectively and separated from one another.

### CROSS-REFERENCE TO RELATED APPLICATION

This application claims the priority benefit of Taiwan application Ser. No. 113111376, filed on Mar. 27, 2024. The entirety of the above-mentioned patent application is hereby incorporated by reference herein and made a part of specification.

### BACKGROUND

### Technical Field

This disclosure relates to a light emitting diode and a manufacturing method thereof.

### Description of Related Art

Light emitting diodes have the advantages of high conversion efficiency, long service life, small size and high safety, and have become a new generation of lighting sources. In addition, the light emitting diodes have also replaced the traditional cold cathode tubes as back light of the display panel. It is especially suitable for smaller portable electronic devices, such as notebook computers, mobile phones and tablet computers.

Compared with traditional display technologies such as liquid crystal displays (LCDs) and organic light emitting diode (OLED) displays, micro light emitting diode (Micro-LED) displays have potential advantages such as high contrast, fast response speed, wide color gamut, low power consumption and long life span, etc. However, there are still many cost and technical bottlenecks that need to be overcome for achieving commercial mass production. For example, in the manufacturing process of light emitting diode, epitaxial material is grown on a sapphire substrate mainly through metal-organic chemical vapor deposition (MOCVD) to form the light emitting diode (LED) epitaxial wafer. The LED epitaxial wafer is etched to form a plurality of etched trenches and a plurality of mesas on a surface of the LED epitaxial wafer, and then the light LED epitaxial wafer is diced along the etching trenches to complete the manufacture of a plurality of LED dies. However, during the etching process of the LED epitaxial wafer, defects and dangling bonds would be formed on the etched sidewalls of the mesas, which causes non-radiative recombination occurring on the etched side walls of the light emitting diode, thereby affecting luminosity of the light emitting diode. Such problems have more significant impact on micro light emitting diodes, due to the small size of the mesas of micro light emitting diodes, the non-radiative recombination occurring in the etched sidewalls would have a considerable impact on the luminosity of the micro light emitting diode.

### SUMMARY

The present disclosure provides a light emitting diode includes a first type semiconductor pattern disposed over a substrate, an active pattern disposed over the first type semiconductor pattern, a second type semiconductor pattern disposed over the active pattern, an ion implantation region and a plurality of electrodes. A polarity of the first type semiconductor pattern is opposite to a polarity of the second type of the second type semiconductor pattern. The ion implantation region at least surrounds and encapsulates a side wall of the second type semiconductor pattern. The electrodes are disposed over the first type semiconductor pattern and the second type semiconductor pattern respectively and separated from one another.

The present disclosure provides a manufacturing method of a light emitting diode including the following steps. A plurality of semiconductor stacking layers are formedover the substrate, wherein the plurality of semiconductor stacking layers comprise a first type semiconductor layer, an active layer, and a second type semiconductor layer with opposite polarity to the first type semiconductor layer stacked over the substrate sequentially. An ion implantation process is performed over a peripheral region of the plurality of semiconductor stacking layers. A patterning process is performed over the plurality of semiconductor stacking layers to form a semiconductor stacking structure, which comprises a first type semiconductor pattern, an active layer pattern and a second type semiconductor pattern stacked over the substrate sequentially, wherein a peripheral region of the second type semiconductor pattern comprises an ion implant region. A plurality of electrodes are formed over the first type semiconductor pattern and the second type semiconductor pattern respectively, wherein the plurality of electrodes are separated from one another.

In light of the foregoing, a light emitting diode and manufacturing method of thereof in present disclosure forms an ion implant region by performing an ion implantation process in a peripheral region of the semiconductor stacking layers, such that the ion implant region surrounds at least a portion of the sidewall of the semiconductor stacking structure (at least encapsulating the sidewall of the second type semiconductor pattern), so as to destroy semiconductor lattice of the ion implant region, thereby reducing the issue of non-radiative recombination on the sidewall of the semiconductor stacking structure caused by the etching process. Therefore, the light emitting diode and the manufacturing method thereof in the disclosure effectively improve light extraction efficiency of the light emitting diode.

### BRIEF DESCRIPTION OF THE DRAWINGS

FIG. 1 to FIG. 7 illustrate cross-sectional views of a manufacturing process of a light emitting diode according to an embodiment of the present disclosure.

FIG. 8 illustrates a schematic curve chart showing the relationship between sizes and light extraction efficiencies of light emitting diodes according to an embodiment of the present disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts. The terms used herein such as “on”, “above”, “below”, “front”, “back”, “left” and “right” are for the purpose of describing directions in the figures only and are not intended to be limiting of the disclosure. Further, in the discussion and claims herein, the term “on” used with respect to two materials, one “on” the other, means at least some contact between the materials, while “over” and “overlie” mean the materials are in proximity, but possibly with one or more additional intervening materials such that physical contact is possible but not required. Neither “on” nor “over” implies any directionality as used herein.

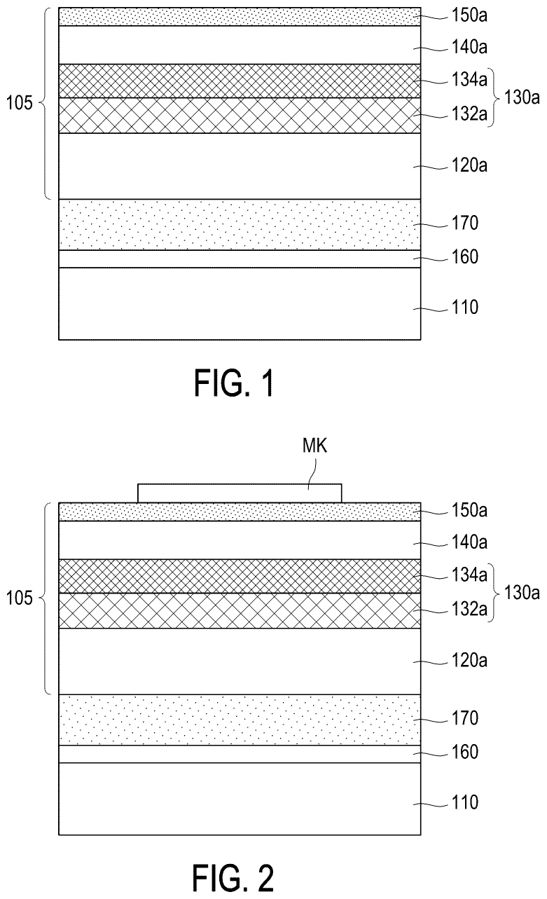

FIG. 1 to FIG. 7 illustrate cross-sectional views of a manufacturing process of a light emitting diode according to an embodiment of the present disclosure. A light emitting diode of the disclosure may be a complete product or a portion of a light emitting diode, or one of multiple steps in a manufacturing process of a light emitting diode. In some embodiments, a manufacturing method of a light emitting diode may include the following steps. First of all, referring to FIG. 1, a plurality of semiconductor stacking layers 105 are formed over a substrate 110, wherein the semiconductor stacking layers 105 include a first type semiconductor layer 120a, an active layer 130a, and a second type semiconductor layer 140a sequentially stacked over the substrate 110, and a polarity of the second type semiconductor layer 140a is opposite to a polarity of the first type semiconductor layer 120a. The material of the substrate 110 may include sapphire, oxide monocrystalline, silicon carbide (SiC), silicon (Si), zinc oxide (ZnO), gallium arsenide (GaAs), magnesium aluminate (MgAl₂O₄) and/or other suitable materials. In this embodiment, the substrate 110 may further include other film layers such as a buffer layer 160 (e.g., a buffer GaN layer), an intermediate layer 170 (e.g., an un-doped GaN layer), a reflective layer, and/or other suitable film layers. Any of the above-mentioned film layers can be obtained through an epitaxial process or formed by other methods.

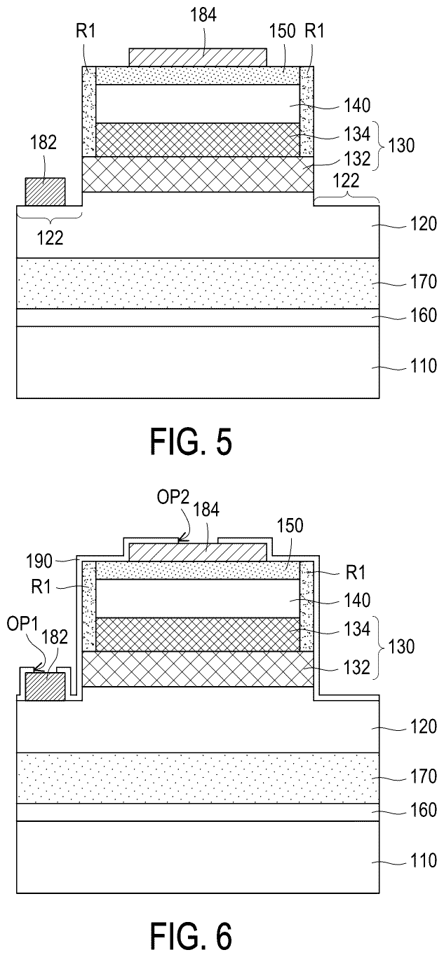

Semiconductor stacking layers 105 are sequentially grown on substrate 110, wherein, the first type semiconductor layer 120a may include III-V material, such as GaN, and may be p-doped (e.g., doped with Mg, Ca, Zn, or Be) or n-doped (e.g., doped with Si or Ge). The active layer 130a can be grown over the first type semiconductor layer 120a to form an active region. The active layer 130a may include III-V materials, such as one or more InGaN layers, one or more AlGaInP layers, and/or one or more GaN layers, and these stacking layers may form one or more hetero structures, such as at least one Quantum well or Multiple Quantum Well (MQW). The second type semiconductor layer 140a can be grown over the active layer 130a. The second type semiconductor layer 140a may include III-V material, such as GaN, and may be p-doped (e.g., doped with Mg, Ca, Zn, or Be) or n-doped (e.g., doped with Si or Ge). One of the first type semiconductor layer 120a and the second type semiconductor layer 140a may be a p-type layer (for example, having p-type electrical property, p-GaN), and the other may be an n-type layer (for example, having n-type electrical property, n-GaN). In this embodiment, the second type semiconductor layer 140a is a p-type semiconductor layer disposed above the substrate 110 and the first type semiconductor layer 120a is an n-type semiconductor layer disposed between the second type semiconductor layer 140a and the substrate 110. However, this disclosure is not limited thereto. The active layer 130a is sandwiched between the first type semiconductor layer 120a and the second type semiconductor layer 140a to form a light emitting area. For example, the active layer 130a may be formed by multiple layers stacked over one another. In this embodiment, the active layer 130a may at least include a GaN barrier layer 132a and an InGaN layer 134a formed over the GaN barrier layer 132a. The first type semiconductor layer 120a may be an n-type GaN layer doped with silicon or oxide, and the second type semiconductor layer 140a may be a p-type GaN layer doped with magnesium, but the disclosure is not limited thereto. In some embodiments, the semiconductor stacking layers may further include an InGaN layer 150a, which may be formed on the second type semiconductor layer 140a, and may be used to form an ohmic contact and reduce the contact impedance of the device. In some embodiments, an electrode (such as electrode 184 shown in FIG. 5) may be formed on the InGaN layer 150a.

Referring to FIG. 2, a mask layer MK is formed on the second type semiconductor layer 140a. In one embodiment, the mask layer MK may cover a central region of the second type semiconductor layer 140a and expose a peripheral region of the second type semiconductor layer 140a as shown in FIG. 2. In this embodiment, the material of the mask layer MK may include nickel or other suitable mask materials.

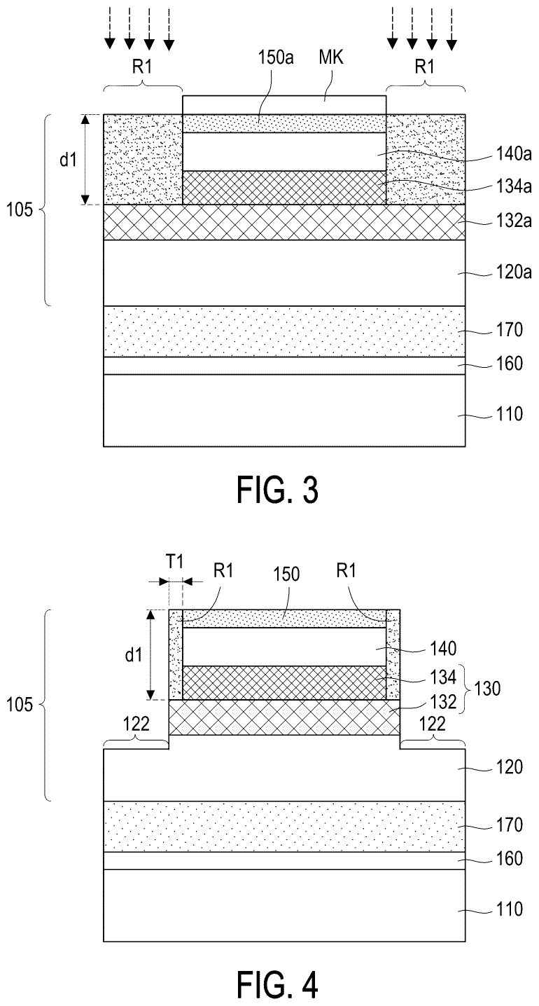

Next, referring to FIG. 3, using mask layer MK as a mask, to perform an ion implantation process on the peripheral region of the semiconductor stacking layers 105 exposed by the mask layer MK, so that the area in the semiconductor stacking layers 105 that has undergone the ion implantation process is formed as an ion implant region R1. In one embodiment, the ion implantation process may be performed by an ion implantation device such as a high current ion implanter, a medium current ion implanter, and/or a high energy ion implanter. For example, the ions that are implanted may include boron (B), phosphorus (P), arsenic (As), boron fluoride (BF_{X}), argon (Ar), nitrogen (N), silicon (Si), fluorine (F), carbon fluoride (CF_{X}), magnesium (Mg), combinations thereof or other ions suitable for implantation. The depth d1 of the ion implant region R1 is related to the implantation temperature and/or ion implantation energy.

In one embodiment, the implantation process can be performed at a temperature close to about room temperature and close to about −100° C. In some embodiments, the ion implantation energy of the ion implantation process is between about 60 keV and about 80 keV. In this way, the depth of the ion implant region R1 can range from about 300 nanometers to about 450 nanometers. The ion implant region R1 formed by such process would surround the peripheral region of the semiconductor stacking layers 105 and extend downward from the top surface of the semiconductor stacking layers 105 away from the substrate 110 to at least surround and encapsulates a portion of the second type semiconductor pattern 140a. In some embodiments, the ion implant region R1 at least surrounds and encapsulates the sidewalls of the second type semiconductor layer 140a. In this embodiment, in addition to surrounding the sidewall of the second type semiconductor layer 140a, the ion implant region R1 can also extend to at least an upper part of the sidewalls of the active layer 130a (for example, extends toward and encapsulates the sidewalls of the InGaN layer 134a). In other embodiments, the ion implant region R1 can further extend toward and encapsulate the sidewalls of entire the active layer 130a (for example, extend toward and encapsulate the sidewall of the GaN barrier layer 132a), or even extend toward and encapsulate an upper part of the first type semiconductor layer 120a. The disclosure is not limited thereto. In one embodiment, the ion implantation dose ranges from about 1.0E15 to about 1.0E18. In other words, the implanted ion concentration of the ion implant region R1 after the ion implantation process is performed substantially ranges between 1.0E15 and about 1.0E18, and the ion implant region R1 that are implanted accordingly includes ions of boron, phosphorus, Arsenic, boron fluoride, argon, nitrogen, silicon, fluorine, carbon fluoride, magnesium, combinations thereof or other ions suitable for implantation. The above numerical ranges are merely used for illustration, and the present disclosure is not limited thereto.

Next, referring to FIG. 3 and FIG. 4, a patterning process is performed over the semiconductor stacking layers 105 shown in FIG. 3 to form the semiconductor stacking structure 106 (also called a mesa structure) shown in FIG. 4. The patterning process may include dry etching or other suitable processes. The semiconductor stacking structure 106 includes a first type semiconductor pattern 120, an active layer pattern 130, a second type semiconductor pattern 140 and an InGaN layer pattern 150 sequentially stacked over the substrate 110, and the peripheral region of the second type semiconductor pattern 140 includes patterned ion implant region R1. In this embodiment, the patterned ion implant region R1 surrounds and encapsulates at least the sidewalls of the second type semiconductor pattern 140 and at least an upper portion of the sidewalls of the active layer pattern 130 (for example, extends to and encapsulates the sidewalls of the InGaN layer pattern 134). In other embodiments, the ion implant region R1 can further extend to and encapsulate the sidewalls of the entire active layer pattern 130 (for example, extend to and encapsulate the sidewalls of the GaN barrier layer pattern 132), or even extend to and encapsulate a part of the first type semiconductor pattern. 120, this disclosure is not limited thereto. The thickness T1 of the patterned ion implant region R1 may range from about 2 microns to about 20 nanometers. The patterned first type semiconductor pattern 120 includes an extended skirt portion 122 that extends beyond an orthographic projection area of the second type semiconductor pattern 140 over the substrate 110. That is to say, the orthographic projection area of the first type semiconductor pattern 120 over the substrate 110 is greater than (extends beyond) the orthographic projection area of the second type semiconductor pattern 140 over the substrate 110.

Generally speaking, during the process of forming the semiconductor stacking structure 106 through patterning processes such as dry etching, the sidewalls of the semiconductor stacking structure 106 may generate some defects, such as unsaturated bonds, chemical contamination and structural damage, which may reduce internal quantum efficiency (IQE) of the light emitting diode. For example, at the etched surface (sidewall), the atomic lattice structure of the semiconductor layer may be damaged, resulting in “dangling bonds” of unpaired valence electrons. These dangling bonds generate energy levels that do not originally exist in a band gap of semiconductor material, thereby causing non-radiative electron-hole recombination at or near the sidewalls of the semiconductor stacking structure 106, thereby reducing light extraction efficiency of the light emitting diode.

In view of this, the present disclosure adopts an ion implantation process at the peripheral region (ion implant region R1) of the semiconductor stacking structure 106 to destroy the semiconductor lattice of the ion implant region R1 and thereby reduce lateral carrier mobility, so as to reduce the issue of non-radiating recombination. Specifically, bombarding the peripheral region of the semiconductor stacking structure 106 with high-energy ions can cause two effects. First, the lattice of the semiconductor material can become less conductive, so that the current does not diffuse through the entire structure in all directions, but flows vertically through the central region. Secondly, the diffusion rate in the ion implant region R1 is smaller, so ion implantation can be used to reduce the diffusion rate and electron diffusion length.

In some embodiments, the manufacturing method of the present disclosure may further include performing a patterning process (dry etching process) on the semiconductor stacking layers 106, an etching process (wet etching process) is performed on the surface of the semiconductor stacking structure 106 using etchant of potassium hydroxide (KOH), so as to further reduce surface non-radiative recombination by using chemical treatment to etch away highly defective surface materials.

FIG. 8 illustrates a curve chart showing the relationship between sizes and light extraction efficiency of light emitting diodes according to an embodiment of the present disclosure. Furthermore, FIG. 8 presents a chart showing the relationship between the chip size (size of the light emitting diode) and the light extraction efficiency (quantum efficiency) of multiple embodiments in which the sidewall surface of the semiconductor stacking structure 106 is treated differently. In this embodiment, the curve marked with a dot (the bottom curve in FIG. 8) represents an embodiment in which no special treatment is performed on the sidewalls of the semiconductor stacking structure 106, the curve marked with a triangle (the middle curve in FIG. 8) represents an embodiment of the ion implantation process being performed at the peripheral region of the semiconductor stacking layers, the curve marked with a square (the top curve in FIG. 8) represents an embodiment of the ion implantation process being performed at the peripheral region of the semiconductor stacking layers and a wet etching being performed using potassium hydroxide etchant over the sidewalls after the patterning process is performed to form the semiconductor stacking structure 106. As can be seen from FIG. 8, compared with the light emitting diode without any treatments, the light extraction efficiency of the light emitting diode that undergoes an ion implantation process on the peripheral region of the semiconductor stacking layers for forming the ion implant region R1 is significantly improved. The light emitting diode formed by wet etching the sidewalls of the semiconductor stacking structure 106 with potassium hydroxide etchant after the ion implantation process and patterning process are performed has even better light extraction efficiency. Moreover, the smaller the size of the light emitting diode (such as a micro light emitting diode) is, the more significant the increase in the light extraction efficiency due to special treatments such as the above-mentioned ion implantation process and wet etching is. The size of a micro light emitting diode (micro LED) is on the micron or nanometer scale.

Next, a plurality of electrodes 182 and 184 are formed on the first type semiconductor layer 120 and the second type semiconductor layer 140 respectively, and the electrodes 182 and 184 are separated from one another. Specifically, the first electrode 182 is formed on the first type semiconductor pattern 120 and the second electrode 184 is formed on the InGaN layer pattern 150 over the second type semiconductor pattern 140. In this embodiment, the first electrode 182 is disposed on the extended skirt portion 122 of the first type semiconductor layer 120 and is electrically connected to the first type semiconductor layer 120. The second electrode 184 is disposed on the InGaN layer pattern 150 over the second type semiconductor layer 140 and is electrically connected to the second type semiconductor layer 140. In this embodiment, the first electrode 182 and the second electrode 184 can be formed simultaneously in the same process, but the disclosure is not limited thereto.

Next, referring to FIG. 6, a dielectric layer 190 is formed, wherein the dielectric layer 190 covers surfaces of the ion implant region R1, the first type semiconductor pattern 120, the active layer pattern 130 and the second type semiconductor pattern 140, and includes a plurality of openings OP1 and OP2 to expose the first electrode 182 and the second electrode 184 respectively. In some embodiments, the dielectric layer 190 may include an oxide layer, such as a SiO₂ layer. In some embodiments, the dielectric layer 190 may act as a reflector to reflect the emitted light out of the light emitting diode.

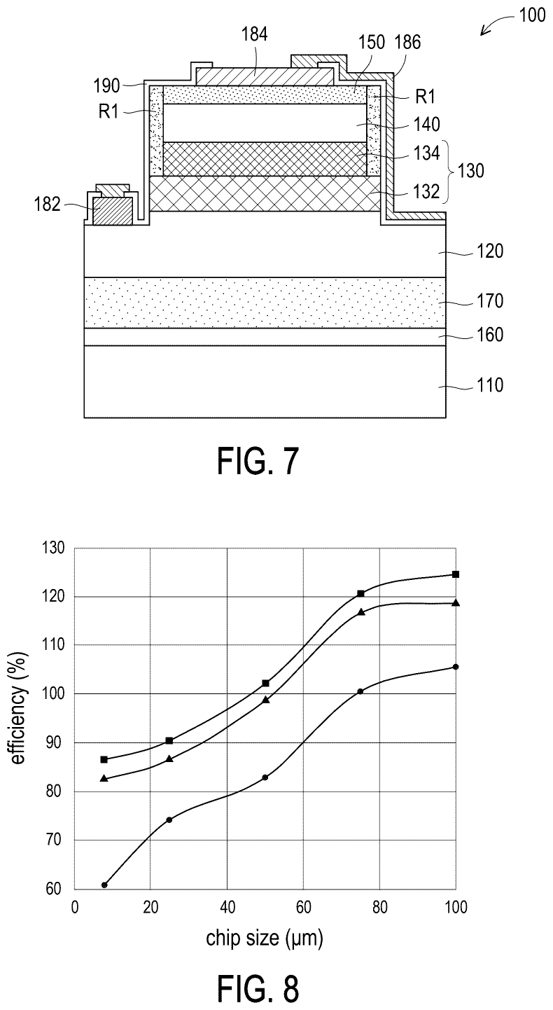

Next, referring to FIG. 7, a circuit layer 186 is formed, and the circuit layer 186 may include a metal layer, such as aluminum (Al), gold (Au), copper (Cu), nickel (Ni), titanium (Ti), any combination thereof, or other suitable of conductive materials. The circuit layer 186 may be formed on the dielectric layer 190 and be electrically connected to the first electrode 182 and the second electrode 184 through the openings OP1 and OP2 respectively. In this way, the manufacturing of the light emitting diode 100 can be substantially completed.

In sum, a light emitting diode and manufacturing method of thereof in present disclosure forms an ion implant region by performing an ion implantation process in a peripheral region of the semiconductor stacking layers, such that the ion implant region surrounds at least a portion of the sidewall of the semiconductor stacking structure (at least encapsulating the sidewall of the second type semiconductor pattern), so as to destroy semiconductor lattice of the ion implant region, thereby reducing the issue of non-radiative recombination on the sidewall of the semiconductor stacking structure caused by the etching process. Therefore, the light emitting diode and the manufacturing method thereof in the disclosure effectively improve light extraction efficiency of the light emitting diode.

What is claimed is:

1. A light emitting diode, comprising:
a substrate;
a plurality of semiconductor stacking layers, comprising:
a first type semiconductor pattern disposed over the substrate;
an active layer pattern disposed over the first type semiconductor pattern;
a second type semiconductor pattern disposed on the active layer pattern, wherein a polarity of the first type semiconductor pattern is opposite to a polarity of the second type semiconductor pattern;
an ion implant region, surrounding a peripheral region of the semiconductor stacking layers and extending downward from a top surface of the semiconductor stacking layers away from the substrate to at least surrounding a portion of the second type semiconductor pattern; and
a plurality of electrodes respectively disposed over the first type semiconductor pattern and the second type semiconductor pattern, and the plurality of electrodes are separated from one another.

2. The light emitting diode as claimed in claim 1, wherein the first type semiconductor pattern comprises an extended skirt portion extending beyond an orthographic projection area of the second type semiconductor pattern over the substrate.

3. The light emitting diode as claimed in claim 1, wherein the plurality of electrodes comprise a first electrode disposed over the extended skirt portion and a second electrode disposed over an upper surface of the second type semiconductor pattern.

4. The light emitting diode as claimed in claim 1, wherein the ion implant region further extends to cover at least an upper part of a sidewall of the active layer pattern.

5. The light emitting diode as claimed in claim 1, wherein the ion implant region comprises ions of boron, phosphorus, arsenic, boron fluoride, argon, nitrogen, silicon, fluorine, carbon fluoride or magnesium.

6. The light emitting diode as claimed in claim 1, further comprising a dielectric layer covering surfaces of the ion implant region, the first type semiconductor pattern, the active layer pattern and the second type semiconductor pattern and exposing the plurality of electrodes.

7. A manufacturing method of a light emitting diode, comprising:
forming a plurality of semiconductor stacking layers over the substrate, wherein the plurality of semiconductor stacking layers comprise a first type semiconductor layer, an active layer, and a second type semiconductor layer with opposite polarity to the first type semiconductor layer stacked over the substrate sequentially;
performing an ion implantation process over a peripheral region of the plurality of semiconductor stacking layers;
performing a patterning process over the plurality of semiconductor stacking layers to form a semiconductor stacking structure, which comprises a first type semiconductor pattern, an active layer pattern and a second type semiconductor pattern stacked over the substrate sequentially, wherein a peripheral region of the second type semiconductor pattern comprises an ion implant region; and
forming a plurality of electrodes over the first type semiconductor pattern and the second type semiconductor pattern respectively, wherein the plurality of electrodes are separated from one another.

8. The manufacturing method of the light emitting diode as claimed in claim 7, further comprising:
forming a mask layer over the second type semiconductor layer before the ion implantation process is performed over the peripheral region of the plurality of semiconductor stacking layers, wherein the mask layer covers a central region of the second type semiconductor layer and exposes a peripheral region of the second type semiconductor layer.

9. The manufacturing method of the light emitting diode as claimed in claim 7, further comprising:
performing an etching process over a surface of the semiconductor stacking structure using potassium hydroxide etchant after the patterning process is performed over the plurality of semiconductor stacking layers.

10. The manufacturing method of the light emitting diode as claimed in claim 7, wherein the ions implanted comprise boron, phosphorus, arsenic, boron fluoride, argon, nitrogen, silicon, fluorine, carbon fluoride or magnesium.
